(19) United States
(12) Patent Application Publication
(10) Pub. No.: US 2015/0355299 A1
(43) Pub. Date: Dec. 10, 2015

(54) METHOD AND APPARATUS FOR OPERATING A MEASURING DEVICE

(71) Applicant: Siemens Aktiengesellschaft, Muenchen (DE)

(72) Inventors: Thomas Blum, Neunkirchen A. Br. (DE); Armin Stranjak, Uttenreuth (DE)

(73) Assignee: SIEMENS AKTIENGESELLSCHAFT, Muenchen (DE)

(21) Appl. No.: 14/731,804

(22) Filed: Jun. 5, 2015

(30) Foreign Application Priority Data
Jun. 5, 2014 (DE) 102014210711.3

(51) Int. Cl. G01R 33/54

(52) U.S. Cl. CPC G01R 33/543

(57) ABSTRACT

The invention concerns a method for operating a measuring (data acquisition) device, particularly a magnetic resonance device of the type, wherein, in each of at least one determination pass, at least one result data record is determined in dependence on a default data record, wherein the result data record has at least one control parameter for controlling the measuring device for the acquisition of measurement data and/or at least one evaluation result determined from the measurement data, and wherein the determination pass includes multiple steps, in each of which an output data record is determined in dependence on an input data record and at least one processing rule, and wherein at least one of the steps is a dependent step in which the input data record of which is determined in dependence on the output data record of at least one further one further step among the multiple steps.

### BACKGROUND OF THE INVENTION

1. Field of the Invention

The invention concerns a method for operating a measuring (data acquisition) device, particularly a magnetic resonance device of the type, wherein, in each of at least one determination pass, at least one result data record is determined in dependence on a default data record, wherein the result data record has at least one control parameter for controlling the measuring device for the acquisition of measurement data and/or at least one evaluation result determined from the measurement data, and wherein the determination pass includes multiple steps, in each of which an output data record is determined in dependence on an input data record and at least one processing rule, and wherein at least one of the steps is a dependent step in which the input data record of which is determined in dependence on the output data record of at least one further one further step among the multiple steps.

2. Description of the Prior Art

Measuring devices in the medical field, especially imaging measuring devices, such as magnetic resonance tomography apparatuses, frequently require complex calculations to determine control parameters for controlling components of the measuring device or for the evaluation of measurement data. Even when powerful computing devices are used, this means that calculations take a long time and hence measuring devices respond especially slowly to user inputs. This is particularly detrimental if, during complex control or evaluation tasks to optimize a result, a number of parameter combinations for control and/or evaluation by a user are tried out one after another.

For example, measuring sequences in magnetic resonance tomography apparatuses are generated in dependence on 200 to 300 different parameters, wherein the different parameters frequently have interdependencies so that a change to only one single parameter can necessitate changes to further parameters in order to facilitate a measurement or ensure adequate quality of the measured values. If one or more parameters of a default measuring sequence are to be changed, in magnetic resonance devices, the user is typically provided with assistance in adapting the measuring sequence in that a validation of the measuring sequence is performed, which, if necessary, automatically adapts the further control parameters. Depending on the type of the sequence and the type of the adaptation, a validation of this can take periods lasting up to tens of second or even several minutes. Frequently, the suggested validated measuring sequence does not exactly correspond to the wishes of the user, so that the parameters of the measuring sequences are determined iteratively in further adaptation and validation steps. Due to the long computing times, a process of this kind takes a lot of time and users perceive the waiting times between the iterative optimization steps as inconvenient.

The aforementioned problems also occur with complex evaluations of measurement data with which individual parameters during the evaluation can greatly influence the quality of the result of an evaluation.

One possible way of shortening these waiting times is to increase the useful computing power for the evaluation of measurement data or the determination of control parameters. However, there are technical limits on the maximum available computing power and an increase in computing power always increases the costs the costs of the measuring device.

### SUMMARY OF THE INVENTION

An object of the present invention is to provide a method for operating a measuring device with which better use can be made of existing computer power during the determination of control parameters and/or during the evaluation of measurement data.

The object is achieved by a method of the type initially described, but wherein parallel to the performance of at least one of the steps, at least one speculative output data record is determined by applying the processing rule of the dependent step in each case to a default speculative input data record, and wherein as the dependent step, in the event of one of the at least one speculative input data record corresponding to the input data record of the dependent step, the speculative output data record assigned to this is provided as an output data record of the dependent step, and otherwise the output data record of the dependent step is determined by applying the processing rule of the dependent step to the input data record of the dependent step.

According to the invention, parallel to the performance of at least one step of the determination of the result data record, the processing rule of a dependent step is applied to a speculative input data record. Therefore, an input data record is “advised” for a dependent step and a speculative output data record is calculated for this “advised” input data record, i.e. the speculative input data record. In the case of the presence of multiple dependent steps, a calculation can be performed for one, several, or all the dependent steps, especially in dependence on the available computing resources. This pre-calculation of speculative output data records enables the time required to perform the dependent step to be significantly reduced during the performance of the dependent step if the input data record of the dependent step corresponds to a speculative input data record for which a speculative output data record has already been determined in advance. In this case, the processing rule for the dependent step no longer has to be applied to the input data record, instead it is also possible directly to provide a speculative output data record assigned to the corresponding speculative input data record as an output data record for the provision of the output data record.

The method according to the invention has the advantage that the power of computing devices is increasingly intensified in form of the parallel performance of computing tasks. Even favorable processors that are commercially available frequently have two or more cores capable of carrying out parallel and substantially independent calculations. The trend is increasingly toward processors with more cores. In addition, multiple processors are often used. It is also possible for further parallelization to be provided within the individual cores. For example, nowadays, numerous processors support so-called SIMD commands (single instruction, multiple data) with which identical computing operations can be performed in parallel for multiple simultaneously available input data flows. At the same time, the increase in performance stagnates for individual cores or instructions to be processed serially. Therefore, for efficient usage of the available computing power, extensive as possible parallelization of individual tasks is expedient.

Here, the problem is that individual steps of a determination pass for the determination of control parameters or an evaluation result frequently depend upon at least one output data record of one or more preceding steps, i.e. are dependent steps. Dependent steps can only be performed when all further steps on which they are dependent have been performed. The execution time of a determination pass determined during a parallelization of steps is, therefore, determined by the degree to which the individual steps are dependent upon one another. If a large number of the steps of the determination pass are dependent steps, the execution time cannot really be shortened by pure parallelization of the steps.

Therefore, in accordance with the invention, a parallel calculation of speculative output data records for the performance of at least one step is performed before a respective dependent step, which enables better use to be made of the available resources, namely parallel computation paths.

In the method according to the invention, the result data record, or a sub-data record of the result data record, can be the output data record of one of the steps. The input data record of at least one of the steps can be identical to the default data record or can include this record. It is also possible for the input data record of at least one of the dependent steps to be identical to the output data record of the further step or to include this record wholly or partially. A dependent step can in each case be dependent on one or more further ones of the steps. At the same time, of the steps it is possible in each case for no, one or a plurality of the dependent steps to be dependent. In particular, a determination pass can have tree-like dependencies between the steps.

The default data record can be determined in dependence on at least one user input. In particular, the default data record can depend on one or more user inputs. Alternatively, an existing data record can be modified by user inputs in order to generate the default data record. For example, a first user input can be used to select a data record which is modified by subsequent user inputs and provided as a default data record.

The default data record of a determination pass can be determined in dependence on a default data record of a, in particular immediately preceding, determination pass. Alternatively or additionally, the default data record of the determination pass can be determined in dependence on a result data record of the preceding determination pass. For example, a user can modify control parameters or parameters influencing an evaluation result iteratively between determination passes, wherein specific modification possibilities can be pre-specified, especially in dependence on the result data record of the preceding determination pass.

It is also possible for the input data record of at least one of the steps to be determined in dependence on a user input or to be this user input or comprise this user input. In this case, this step can only be performed after the acquisition of the user input, i.e. it forms a user-input-dependent step. To enable further parallelization of the determination of the result data record, for the user-input-dependent step, it is also possible to calculate speculative output data records parallel to the performance of at least one of the steps as was described above for dependent steps. In this case, in the user-input-dependent step, if the input data record corresponds to a speculative input data record assigned to the user-input-dependent step, the speculative output data record assigned thereto can be provided as an output data record of the user-input-dependent step. Otherwise, the step can be performed normally.

A number of determination passes with different default data records can be performed, wherein for at least one item of input data of the input data record of at least one of the at least one dependent step, a statistical evaluation is determined via multiple passes of the determination passes. In at least one of the determination passes, the speculative input data record is determined such that the item of input data has the most probable value according to the statistical evaluation or that the speculative input data records are determined such that they have different most probable values for the item of input data according to the statistical evaluation. If, for example, with multiple passes, a default data record is only changed in individual portions of default data of the default data record and these portions of default data are frequently in the same value ranges, it is possible that a corresponding probability distribution will also be present for an item of input data or several items of input data of the input data record. For example, the item of input data or several items of input data could be dependent on a user input such that, for example, normally distributed user inputs are depicted on a normally distributed item of input data or items of input data. Since user inputs of a measuring device frequently correspond to a specific probability distribution, for example a Poisson distribution or a normal distribution, statistical evaluations of at least one item of input data and a corresponding selection of at least one of the at least one speculative input data record can significantly increase the probability of one of the at least one speculative input data record corresponding to the input data record, and hence an acceleration of the determination pass is achieved.

Advantageously, the item of input data can be depicted numerically. If several items of input data are statistically evaluated, it is possible for probabilities for combinations of the input data to be calculated. However, it is also possible to determine a separate statistical evaluation for each item of input data of statistically evaluated input data. The statistical evaluation can, for example, determine the parameters of a Poisson distribution or a normal distribution. Especially, with discrete values, however, it is also possible to determine exclusively a mean value or median.

Alternatively or additionally, user inputs can be acquired statistically during a number of determination passes and at least one speculative input data record can be determined for at least one dependent step in dependence on these statistics. This is possible in the same way as the above-explained determination of a statistical evaluation for at least one item of input data of an input data record of at least one dependent step.

A number of determination passes with different default data records can be performed, wherein, in at least one of the determination passes, the speculative input data record is determined by varying an input data record of the immediately preceding determination pass. The input data record of the immediately preceding step is assigned to the same step as the speculative input data record, i.e. to the dependent step. For variation, it is in particular possible to specify a measure for the distance of the speculative input data record from the input data record, for example a sum of squares of the difference between individual items of data of the input data record and the speculative input data record. The speculative input data record or the speculative input data records can be selected such that they are different from the input data record in the immediately preceding determination pass, wherein, under this condition, the measure for the distance of the speculative input data records from the input data record determined in the immediately preceding determination pass is minimized. A procedure of this kind is particularly advantageous if a default data record is varied between the determination passes in order to optimize the result data record with respect to a default criterion. Independently of whether a corresponding variation takes automatically or in dependence on a user input, it may be typically assumed that the default data record only changes slightly. Depending upon the specific calculations of a determination pass to be performed, it is possible that as a result, the input data record of at least one dependent step is only slightly varied.

It is also possible for a plurality of determination passes with different default data records to be performed, wherein, in each determination pass, the speculative input data records and the assigned speculative output data records are stored and wherein, in at least one of the passes, if the input data record of at least one of the at least one dependent step corresponds to one of stored speculative input data records, the assigned speculative output data record is provided as an output data record of the dependent step. To this end, in each determination pass, pairs of speculative input data records and speculative output data records can be stored, in particular in a database. Hence, a number of determination passes provides a pool of speculative input data records, for which speculative output data records already exist. The result of this is in particular that speculative output data records which have been calculated once can always be reused and the calculation of speculative output data records assigned to speculative input data records, which initially do not correspond to the input data record of the step, is not “wasted”.

Speculative output data records can be determined for at least two different dependent steps, wherein the relative number of the speculative output data records determined, which are in each case determined for the different dependent steps, are specified in dependence on the relative processing times of respective processing rules. Here, it is possible to give preference to a determination for dependent steps whose processing rule has a shorter processing time. In the case of multi-stage dependencies, it is preferable to determine speculative output data records for those dependent steps on whose output data record many other dependent steps depend.

The determination of the speculative data record and the parallel performance of at least one of the steps can in particular be performed on separate computing elements. The separate computing elements can be different cores of a processor and/or different processors. In this case, it is possible for all physically available computing elements to be used; however it is also possible only to use computing elements that are not currently required for other calculations with a higher priority for the calculation of speculative output data records. The number of speculative output data records determined in parallel can be dynamically adapted in dependence on existing or available computing resources, i.e. the computing power, of the memory and/or the current system loading.

The method according to the invention can also be used with other types of parallelization, for example with a calculation on processors with multiple processing pipelines, for example processors in graphics cards, or with processors with SIMD functions (single instruction, multiple data), with which a homogeneous computing operation can be applied to several pieces of data within one command.

It is possible to determine a number of speculative output data records in parallel, wherein each of the speculative output data records is determined on a separate computing element.

A parameter of a measuring sequence for controlling the magnetic resonance device can be determined as the at least one control parameter. In this case, it is possible to specify a sub-group of the parameters of the measuring sequence as a default data record and output a complete measuring sequence or a result data record, which fully parameterizes the measuring sequence, as a result data record. A corresponding measuring sequence or the parameterization of the measuring sequence can be optimized through a number of determination passes.

For example, a user can specify some of the parameters of the measuring sequence, following which, in a first determination pass, the further parameters of the measuring sequence are determined such that the measuring sequence can be performed. A complete parameterization of the measuring sequence can be output as a result data record. The user can be shown a summary of the essential features of the measuring sequence. The user can then be offered a number of modification possibilities for the measuring sequence, for example an adaptation of the repetition time, the slice thickness, the slice number or the resolution, following which a result data record modified in dependence on the user input of the first determination pass can be used as a default data record of the second determination pass. This can be repeated until a user is satisfied with the resulting measuring sequence or the parameterization thereof.

A magnetic resonance spectroscopy data record can be determined as the at least one result data record. In the context of magnetic resonance spectroscopy, in particular, chemical compositions are to be determined. In particular global or local proportional values of certain substances or compounds are calculated as an evaluation result. Different algorithms are available for this purpose, which can also be parameterized. A default data record can comprise the measurement data and a selection of one or more algorithms to use and/or parameterization thereof. With the determination of a magnetic resonance spectroscopy data record, a result determined from the measurement data is again heavily dependent on the choice of algorithms and parameters. However, the effects of the use of individual algorithms or a change to parameters frequently cannot be directly predicted so that a user typically varies the algorithms used and the parameterizations of the algorithms in order to obtain an evaluation result corresponding to default quality standards. The use of the method according to the invention enables the respective computing time for each of these adaptations to be significantly reduced.

The invention also concerns a measuring device designed to perform the method according to the invention. The measuring device can be a magnetic resonance device. At least one computing device of the measuring device preferably has multiple processors and/or at least one processor with multiple processor cores. The use of multiple processors and/or cores makes resources available for parallel calculations. These are used with the measuring device according to the invention, as explained with respect to the method according to the invention, to determine at least one speculative output data record in parallel to the performance of at least one step of a determination pass. This enables the measuring device according to the invention to be developed in accordance with the features explained with respect to the method according to the invention.

### BRIEF DESCRIPTION OF THE DRAWINGS

FIG. 1 is a flowchart of an exemplary embodiment of the method according to the invention.

FIG. 2 is a schematic diagram of computing times of the exemplary embodiment shown in FIG. 1.

FIG. 3 is a flowchart of a further exemplary embodiment of the method according to the invention.

FIG. 4 is a block diagram of the control computer in an exemplary embodiment of a measuring device according to the invention, namely a magnetic resonance device.

### DESCRIPTION OF THE PREFERRED EMBODIMENTS

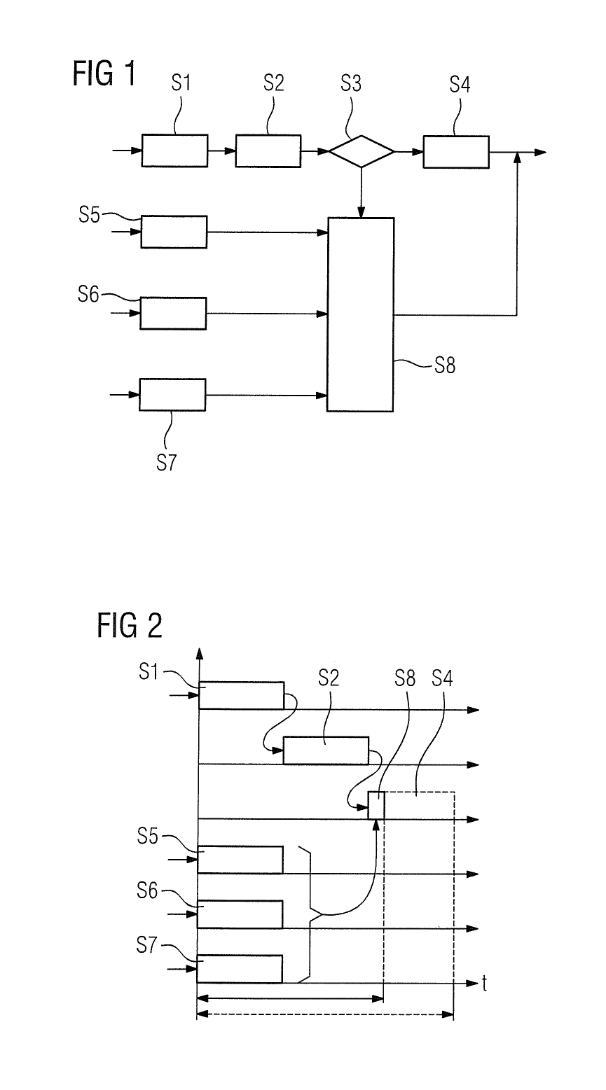

FIG. 1 shows an exemplary embodiment of a method for operating a measuring device with which a result data record is determined in dependence on a default data record. FIG. 2 is a schematic diagram of the computing times used within the context of this method. Here, a determination pass of the method comprises Steps S1, S2, S4, in which in each case an output data record is determined in dependence on an input data record and a processing rule. Steps of this kind will also be described below as processing steps. Here, steps S2 and S4 are dependent steps, whose input data records are in each case determined in dependence on an output data record of a further one of the processing steps. Here, the input data record of Step S2 is identical to the output data record of Step S1 and the input data record of Step S4 is identical to the output data record of Step S2. In alternative embodiments of the method it would be possible, for example, for the output data record of Step S1 to be modified or supplemented in order to form the input data record of Step S2. A modification or supplementation can be made dependent on a user input or the default data record, i.e. of the input data record of Step S1. A result data record is provided as an output data record of Step S4.

Since Steps S2 and S4 are dependent steps, it is also necessary when performing the method on a computing device comprising a plurality of processors and/or cores to perform Steps S1, S2 and S4 one after the other. Therefore, the computing time required is the total of the computing times of Steps S1, S2 and S4. This is elucidated in FIG. 2, wherein Steps S1 and S2 are in each case are depicted as boxes on a separate time line and Step S4 is depicted as a dashed box on a third time line. Each of these time lines describes in each case the occupation of a processor or a core. Hence, even, as shown, Steps S1, S2 and S4 are executed on different processors or cores, the method requires the time indicated by the dashed double arrow, which is the total of the execution times for Steps S1, S2 and S4.

In order, despite the fact that Steps S2 and S4 are dependent steps, to achieve an acceleration of the method by parallelization, Step S3 is provided between step S2 and S4 and a further execution path is provided with Steps S5, S6, S7 and S8. In Steps S5, S6 and S7, a speculative output data record is determined and provided for further processing in each case parallel to the performance of Step S1, by applying the processing rule of Step S4 to a default speculative input data record. The performance of Steps S5, S6 and S7 parallel to step S1 on separate cores or processors is additionally shown in FIG. 2.

Hence, in Step S3, both the speculative output data records of Steps S5, S6, S7 and the output data record of Step S2 and hence the input data record for Step S4 are known. In Step S3, it is determined whether one of the default speculative input data records of Steps S5, S6, S7 corresponds to the input data record of Step S4. If this is not the case, the method is continued as described above with Step S4.

However, if it is determined that the input data record of Step S4 corresponds to one of the speculative input data records of Steps S5, S6, S7, the method is continued with Step S8. In Step S8, the speculative output data record of that of Steps S5, S6, S7 is provided as an output data record, the speculative input data record of which corresponds to the input data record of Step S4. Hence, Step S8 exclusively entails a selection of one of a plurality of values. Hence, as shown in FIG. 2, Step S8 can be performed much more quickly than Step S4 thus shortening the overall execution time as represented by the double arrow in FIG. 2. The method shown enables a significant shortening of the execution time for a determination pass possible if there are multiple processors or cores of processors.

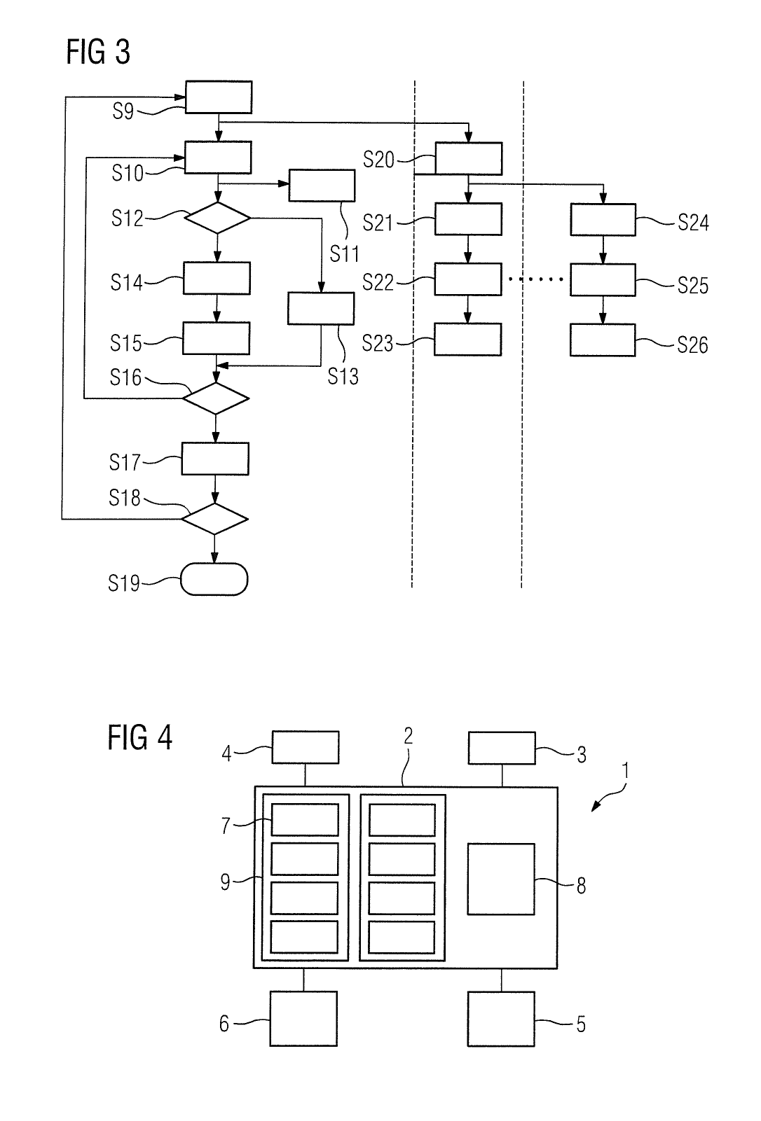

FIG. 3 is a schematic diagram of a further method for operating a measuring device in which a result data record is determined in a number of determination passes in each case in dependence on a default data record. To this end, in Step S9, a default data record is specified or an already existing data record is modified in order to specify a default data record. In particular user inputs can be acquired as a default data record. Here, in particular a first user input can select an already existing data record which can be modified by further user inputs. It is in particular possible in the second and subsequent determination passes for the respective default data records to be specified in dependence on the default data record of the immediately preceding determination pass and/or in dependence on the result data record of the immediately preceding determination pass. For example, a result data record can be optimized with respect to specific default criteria in that a default data record is varied automatically or in each case in dependence on a user input.

Each of the determination passes comprises a plurality of processing steps in which in each case an output data record is determined in dependence on an input data record and at least one processing rule. In FIG. 3, a processing step of this kind is divided into Sub-steps S11-S15. The different processing steps differ in the way their input data records are provided and in their processing rules, which describe the transition from input data record to output data record.

As far as possible, each determination pass should be parallelized so that processing steps do not necessarily have to be performed in a fixed sequence. In Step S10, in each case one of the processing steps to be is selected. Here, a processing step is selected for an input data record already present or can be determined. A dependent processing step the input data record of which is determined in dependence on the output data record of at least one of the further processing steps is, therefore, only performed when all processing steps on whose output data records an input data record depends have been performed.

In Sub-step S11, a statistical evaluation is performed for at least a part of the input data of the input data record. To this end, the part of the input data is stored in each determination pass and a statistical distribution of the part of the input data are determined in dependence on the stored data.

In Sub-step S12, it is checked whether the input data record of the processing step corresponds to a speculative input data record stored in a database or a input data record, for which an output data record has already been determined in the corresponding processing step in a preceding determination pass. The use of speculative input data records or the calculation of speculative output data records will be explained later with reference to Steps S20 to S26.

If a correspondence of this kind is determined, an output data record for the processing step is provided in Sub-step S13. If the input data record corresponds to an input data record of the corresponding processing step of a preceding determination pass, the corresponding output data record of the processing step in the preceding determination pass is read from the database and provided as an output data record of the step. If the input data record corresponds to a speculative input data record, the speculative output data record assigned to this will be provided as an output data record of the step.

However, if no correspondence was determined in Sub-step S12, the method is continued with Sub-step S14 in that the output data record of the processing step is determined by applying the processing rule of the processing step to the input data record. In Sub-step S15, the output data record determined is stored in a database.

It is then checked in Step S16 whether all processing steps for the current determination pass have already been performed. If this not the case, the method is continued in S10. However, if all processing steps of the current determination pass have been performed, the method is continued in Step S17 in that a result data record is provided. Here, the result data record is the output data record of one of the processing steps.

In Step S18, it is determined whether further determination passes need to be performed. If this is the case, the method is continued in Step S9. If this is not the case, the method ends in Step S19. Parallel to the performance of Sub-steps S11 to S15, speculative output data records are determined for one or more processing steps on further processors or cores. In Step S20, a processing step is selected for which the speculative output data records are to be determined. During the determination of how many speculative output data records are to be determined for different processing steps, the execution time of the respective steps is taken into account, as well as how many dependent processing steps are dependent on the output data record of the respective processing step.

In Step S21, a speculative input data record is determined. Here, the speculative input data record is determined in dependence on the statistical evaluation determined in Step S11 of the preceding determination pass, wherein the speculative input data record is determined such that all the speculative input data records considered have different statistically most probable values for the part of the input data statistically evaluated in Step S11.

In Step S22, the processing rule of the processing step selected in Step S20 is applied to the speculative input data record in order to determine a speculative output data record which is stored in the database in Step S23.

Steps corresponding to Steps S21 to S23 can be performed as often as desired in parallel for different or similar processing steps and/or for different speculative input data records on further processors or cores. This is indicated by Steps S24 to S26 and the dotted line between Steps S21 to S23 and S24 to S26. Steps S24 to 26 correspond to Steps S21 to S23.

FIG. 4 is a flowchart of a control component of a magnetic resonance device 1 embodied to perform the above method explained with reference to FIG. 3. The magnetic resonance device 1 has a computing device 2, a field control 3 embodied for controlling magnets and coils (not shown) of the magnetic resonance device 1, a data acquisition device 4, which collects data from receiving coils of the magnetic resonance device, preprocesses them and provides them to the computing device 2, input components 5 for the acquisition of user inputs and output means 6 for depicting information for a user. The computing device 2 has two separate processors 9, each having four cores 7. The computing device 2 also has a storage device 8 with a database, in which speculative input data records and associated speculative output data records, statistics on input data records and the like can be stored. Here, the magnetic resonance device 1 is operated such that, as explained above, with the performance of a determination pass for the determination of a result data record in dependence on a default data record, parallel to the performance of at least one processing step of the determination pass on one of the cores 7, speculative output data records are determined on at least one other core 7.

Although modifications and changes may be suggested by those skilled in the art, it is the intention of the inventors to embody within the patent warranted hereon all changes and modifications as reasonably and properly come within the scope of their contribution to the art.

We claim as our invention:

1. A method for operating a measuring device, comprising:
in a computer, executing at least one determination pass and, in each determination pass in said computer, determining one result data record dependent on a default data record accessible by the computer, said result data record comprising at least one control parameter derived from measurement data of the measuring device, said control parameter being configured to control the measuring device in a procedure selected from the group consisting of acquiring said measurement data and evaluating said measurement data;
in said computer, executing each determination pass as a plurality of determination pass steps, in each of which an output data record is determined dependent on an input data and on at least one processing rule, with at least one of said plurality of determination pass steps being a dependent step that is determined dependent on the output data record of at least one other determination pass step in said plurality of determination pass step;
in said computer, in parallel with execution of at least one of said plurality of determination pass steps, determining at least one speculative output data record by applying the processing rule of said at least one dependent step to one default speculative input data record;
in said at least one dependent step, if the at least one speculative input data record corresponds to the input data record of said at least one dependent step, assigning the speculative output data record to the corresponding input data record, as an output data record for said at least one dependent step;
if said at least one speculative input data record does not correspond to the input data record of said at least one dependent step, determining the output record of said at least one dependent step by applying the processing rule of the at least one dependent step to the input data record of the dependent step; and
from said computer, making at least said output data record of said at least one dependent step available in electronic form.

2. A method as claimed in claim 1 comprising making at least one user input into said computer, and determining said default data record dependent on said at least one user input.

3. A method as claimed in claim 1 comprising executing said plurality of determination passes using respectively different default data records in the respective determination passes and, for at least one item of input data of the input data record of said at least one dependent step, making a statistical evaluation from said plurality of determination passes and determining said speculative input data record as a speculative input data record in which said item of input data has a most probable value according to the statistical evaluation, or determining a plurality of speculative input data records having different respective values for said item of input data according to said statistical evaluation.

4. A method as claimed in claim 1 comprising performing said plurality of determination passes with respectively different default data records and, in at least one of said determination passes, determining said speculative input data record by varying an input data record of the immediately preceding determination pass.

5. A method as claimed in claim 1 comprising executing said plurality of determination passes with respectively different default data records and, in each determination pass, storing the speculative input data record therefor and the speculative output data record assigned thereto and, in at least one of said determination passes, if the input data record of said at least one dependent step corresponds to one of the stored speculative input data records, assigning the speculative output data record, that is assigned to the stored corresponding speculative input data record, as the output data record of said at least one dependent step.

6. A method as claimed in claim 1 comprising determining a respective speculative output data record in each of at least two different dependent steps, and determining a relative number of speculative output data records respectively determined for the different dependent steps, in dependents on relative processing times of the respective processing rules of said different dependent steps.

7. A method as claimed in claim 1 comprising determining said speculative output data record in a first computer, and performing said steps in parallel with said performance of said plurality of determination passes, in a second computer that is separate from said first computer.

8. A method as claimed in claim 1 within said measuring device is a magnetic resonance apparatus, that executes, as said process, a magnetic resonance data measuring sequence, and using a parameter of said magnetic resonance data measuring sequence as said at least one control parameter.

9. A method as claimed in claim 8 comprising generating a magnetic resonance spectroscopy data record as said at least one result data record.

10. A measuring apparatus comprising:
a measuring device configured to execute a procedure selected from the group consisting of acquiring measurement data and evaluating measurement data, said procedure being controlled dependent on at least one control parameter;
a computer configured to execute at least one determination pass and, in each determination pass, determine one result data record dependent on a default data record accessible by the computer, said result data record comprising at least one control parameter derived from measurement data of the measuring device, said control parameter being configured to control the measuring device in a procedure selected from the group consisting of acquiring said measurement data and evaluating said measurement data;
said computer being configured to execute each determination pass as a plurality of determination pass steps, in each of which an output data record is determined dependent on an input data and on at least one processing rule, with at least one of said plurality of determination pass steps being a dependent step that is determined dependent on the output data record of at least one other determination pass step in said plurality of determination pass step;
said computer being configured to determine, in parallel with execution of at least one of said plurality of determination pass steps, at least one speculative output data record by applying the processing rule of said at least one dependent step to one default speculative input data record;
in said at least one dependent step, if the at least one speculative input data record corresponds to the input data record of said at least one dependent step, said computer being configured to assign the speculative output data record to the corresponding input data record, as an output data record for said at least one dependent step;
if said at least one speculative input data record does not correspond to the input data record of said at least one dependent step, said computer being configured to determine the output record of said at least one dependent step by applying the processing rule of the at least one dependent step to the input data record of the dependent step; and
said computer being configured to make at least said output data record of said at least one dependent step available in electronic form.
